(19) United States
(12) Patent Application Publication
(10) Pub. No.: US 2017/0294568 A1
(43) Pub. Date: Oct. 12, 2017

(54) PIEZOELECTRIC OSCILLATION COMPONENT AND METHOD FOR MANUFACTURING THE SAME

(71) Applicant: Murata Manufacturing Co., Ltd., Nagaokakyo-shi (JP)

(72) Inventor: KAZUYUKI NOTO, Nagaokakyo-shi (JP)

(21) Appl. No.: 15/631,383

(22) Filed: Jun. 23, 2017

Related U.S. Application Data
(63) Continuation of application No. PCT/JP2015/074264, filed on Aug. 27, 2015.

(30) Foreign Application Priority Data
Jan. 8, 2015 (JP) 2015-002384

(51) Int. Cl. H01L 41/053; H01L 41/31; H01L 41/23; H01L 41/09

(52) U.S. Cl. CPC H01L 41/053; H01L 41/09; H01L 41/31; H01L 41/23

(57) ABSTRACT

Bonding strength with which a substrate and an adhesive layer are bonded together to seal a piezoelectric vibrator on the substrate is enhanced. A piezoelectric vibration component includes a lid including a recess and a flange protruding outward from an opening edge of the recess. Moreover, the component includes a substrate having a first area opposing the recess and a second area opposing the flange. A piezoelectric vibrator is mounted on the first area, and an adhesive layer bonds the second area and the flange together to seal the piezoelectric vibrator in a space between the recess and the first area. The second area has surface roughness greater than surface roughness of the first area.

### CROSS REFERENCE TO RELATED APPLICATIONS

The present application is a continuation of PCT/JP2015/074264 filed Aug. 27, 2015, which claims priority to Japanese Patent Application No. 2015-002384, filed Jan. 8, 2015, the entire contents of each of which are incorporated herein by reference.

### TECHNICAL FIELD

The present disclosure relates to a piezoelectric oscillation component and a method for manufacturing the same.

### BACKGROUND

Piezoelectric oscillators have been widely used as oscillators or bandpass filters. For example, Japanese Unexamined Patent Application Publication No. 2014-197615 (referred to as “Patent Document 1”) discloses, discloses an example of an existing piezoelectric oscillator, in which a surface mount quartz oscillator has a structure in which the quartz oscillator is sealed from the outside air. As described therein, the surface mount quartz oscillator disclosed by Patent Document 1 includes a substrate on which a quartz oscillator is mounted and a lid that seals the quartz oscillator using an adhesive.

In the design of Patent Document 1, if the bonding strength between the substrate and the adhesive is insufficient, the lid may be detached from the substrate. For example, the wettability of the adhesive decreases when the substrate has low surface roughness. In this case, the bonding strength between the substrate and the adhesive is likely to be low. Particularly, when the quartz oscillator is to be sealed by joining the lid and the substrate together using a thermosetting adhesive, the pressure inside the lid rises due to reflow heating temperatures around 260° C. so that the lid is detached from the substrate in some cases.

### SUMMARY

The present disclosure addresses the above-described circumstances and enhances bonding strength between a substrate and an adhesive layer that seal a piezoelectric oscillator on the substrate.

Thus, a piezoelectric oscillation component according to an exemplary aspect is provided that includes a lid including a recess and a flange portion that protrudes outward from an opening edge of the recess. Moreover, the piezoelectric oscillation component includes a substrate having a first area opposing the recess and a second area opposing the flange portion, a piezoelectric oscillator mounted on the first area, and an adhesive layer that bonds the second area and the flange portion together to seal the piezoelectric oscillator in a space between the recess and the first area. According to the exemplary aspect, the second area has surface roughness greater than surface roughness of the first area.

The present disclosure enhances bonding strength between a substrate and an adhesive layer that seal a piezoelectric oscillator on the substrate.

### BRIEF DESCRIPTION OF DRAWINGS

FIG. 1 is an exploded perspective view of a piezoelectric oscillation component according to a first embodiment of the present invention.

FIG. 2 is a sectional view of a process of manufacturing the piezoelectric oscillation component according to the first embodiment of the present invention.

FIG. 3 is a sectional view of a process of manufacturing the piezoelectric oscillation component according to the first embodiment of the present invention.

### DETAILED DESCRIPTION

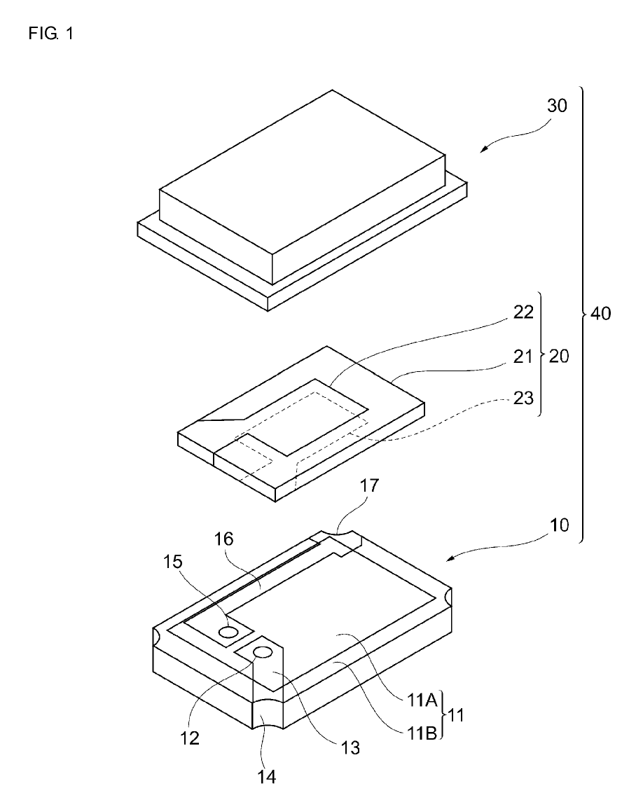

Now, a first embodiment of the present invention is described below with reference to FIGS. 1 to 4.

FIG. 1 is an exploded perspective view of a piezoelectric oscillation component 40 according to the first embodiment of the present invention. As illustrated in FIG. 1, a piezoelectric oscillation component 40 mainly includes a piezoelectric oscillator 20, a substrate 10 having a main surface 11 on which the piezoelectric oscillator 20 is mounted, and a lid 30 that hermetically seals the piezoelectric oscillator 20 from the outside air. The piezoelectric oscillator 20 includes a flat piezoelectric plate 21 having two surfaces opposing in the thickness direction, an excitation electrode 22 on one of the surfaces of the piezoelectric plate 21, and an excitation electrode 23 on the other surface of the piezoelectric plate 21. When an AC voltage is applied across the excitation electrodes 22 and 23, the piezoelectric plate 21 oscillates in a thickness shear mode. The piezoelectric plate 21 is formed from a piezoelectric material (such as a quartz plate or piezoelectric ceramics, for example). The excitation electrodes 22 and 23 are conductive thin films made of, for example, gold, chromium, nickel, aluminum, or titanium.

The substrate 10 is a flat plate having two surfaces opposing in the thickness direction. Of the two surfaces, the surface on which the piezoelectric oscillator 20 is mounted is referred to as a main or principal surface 11. A wire 13 electrically connected to the excitation electrode 23 through a conductive adhesive 12 and a wire 16 electrically connected to the excitation electrode 22 through a conductive adhesive 15 are disposed on the main surface 11. The substrate 10 is formed from a material having appropriate mechanical strength and appropriate electric insulation properties (for example, insulating ceramics such as alumina, a synthetic resin, or a composite formed by coating the surface of a metal plate with an insulating layer). Moreover, as shown, the substrate 10 can have indentations 14 and 17, formed by partially cutting corner portions so as to have a cylindrical curved surface. The wires 13 and 16 respectively extend from the indentations 14 and 17 to the surface opposite to the main surface 11 so as to be connectable to an outside circuit.

The lid 30 is a closed-end lid member that hermetically seals the piezoelectric oscillator 20 from the outside air. As illustrated in FIG. 3, the lid 30 includes a recess 31, which opens toward the main surface 11, and a flange portion 32, which protrudes outward from the opening edge of the recess 31. The recess 31 is a closed-end recess set back in the lid 30. The recess 31 has an opening area and an opening depth large enough to enclose the piezoelectric oscillator 20. The flange portion 32 surrounds the periphery of the recess 31 in a substantially continuous rectangle. In an exemplary aspect, the lid 30 may be formed from a metal material, an insulating material, or a composite (such as a composite formed by coating the surface of an insulating member with a metal thin film). The main surface 11 of the substrate 10 has a first area 11A, opposing the recess 31, and a second area 11B, opposing the flange portion 32. The second area 11B is formed in a substantially frame shape so that the flange portion 32 is appropriately joined to a right portion of the main surface 11 to surround the piezoelectric oscillator 20. An adhesive layer 50 joins the second area 11B of the substrate 10 and the flange portion 32 of the lid 30 together so that the piezoelectric oscillator 20 is hermetically sealed in the gap between the recess 31 and the first area 11A. It is noted that the adhesive layer 50 is not particularly limiting and may be any insulating adhesive including, for example, a nonconductive adhesive that cures with heat and that has bonding properties. For example, the adhesive can be an epoxy-based adhesive containing an epoxy resin as a main component. Moreover, an epoxy resin can include a bifunctional epoxy resin, such as a bisphenol A epoxy resin or a bisphenol F epoxy resin, and a novolac epoxy resin, such as a phenolic novolac epoxy resin or a cresol novolac epoxy resin. Generally known epoxy resins such as a multifunctional epoxy resin, a glycidyl amine epoxy resin, a heterocycle containing epoxy resin, or an alicyclic epoxy resin are also usable. It is reiterated that the material of the adhesive layer 50 is not limited to an epoxy-based adhesive and may be, for example, a low-melting-point glass adhesive. A low-melting-point glass adhesive may contain a lead-free vanadium-based glass that melts at temperatures within the range of 300° C. to 410° C. The vanadium-based glass exerts a bonding effect when a binder and a solvent are added to the glass paste and the mixture is melt and vitrified. When bonded, the vanadium-based glass has reliably high properties such as airtightness, watertightness, and moistureproofness. The coefficient of thermal expansion of the vanadium-based glass is flexibly controllable by controlling the glass structure. The lid 30 may be referred to as a cap, a cover, or a packaging member.

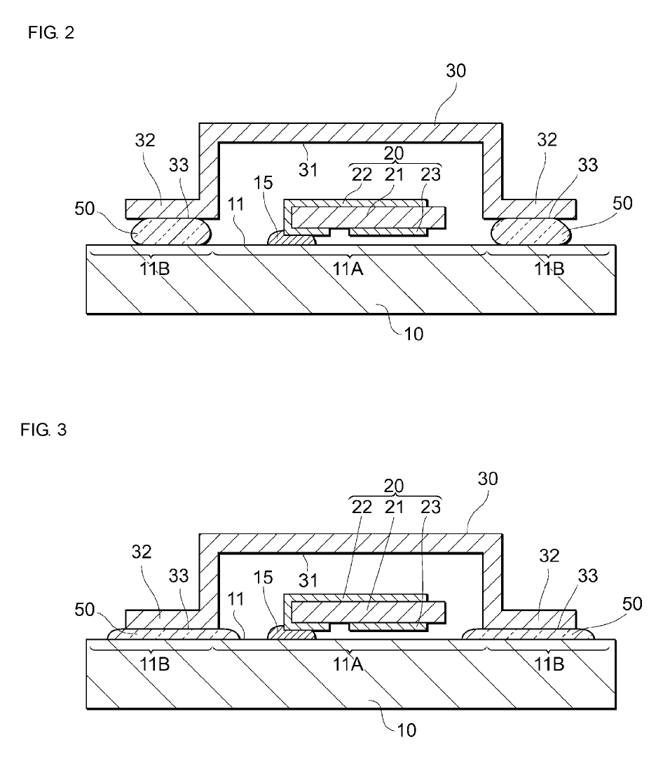

Exemplary processes of manufacturing the piezoelectric oscillation component 40 are described now, with reference to FIGS. 1 to 3. First, as illustrated in FIG. 1, the substrate 10 having the second area 11B is prepared. The second area 11B is subjected to surface roughening so as to have surface roughness greater than the surface roughness of the first area 11A. Specific examples of surface roughening include plasma treatment and sandblasting. Sandblasting is a process performed to roughen the workpiece surface to have an uneven cross section by ejecting, for example, fine particles (for example, abrasive particles such as alumina or diamond) toward the workpiece surface together with compressed air. When a single mother substrate is cut into multiple substrates 10 to manufacture multiple piezoelectric oscillation components 40, sandblasting is performed using a mask disposed so as to leave the second areas 11B open. Subsequently, as illustrated in FIG. 2, the piezoelectric oscillator 20 is mounted on the first area 11A and the adhesive layer 50 is formed over the second area 11B. Here, preferably, the adhesive layer 50 is applied with a uniform thickness so as to uniformly spread over the second area 11B.

Subsequently, as illustrated in FIG. 3, the lid 30 and the substrate 10 are pressed against each other so that the piezoelectric oscillator 20 is enclosed in the space between the recess 31 of the lid 30 and the first area 11A of the substrate 10. Then, the adhesive layer 50 is heated to hasten intermolecular bond between molecules constituting the adhesive layer 50 and shifted to the cured state. Thus, the piezoelectric oscillator 20 can be hermetically sealed in the space between the recess 31 and the first area 11A. The contact angle of a droplet is generally known as being sensitive to the surface roughness. Here, the surface roughness can be defined as an area ratio of the roughened surface to the flat surface. For example, as the surface roughness increases, the contact angle of a droplet decreases (wettability increases) on a lyophilic surface or increases (wettability decreases) on a lyophobic surface. Based on such knowledge, the material of the lid 30 is selected so that the lid 30 is lyophilic to the adhesive layer 50 and the second area 11B has surface roughness greater than the surface roughness of the first area 11A, so that the contact angle of the adhesive layer 50 in the second area 11B can be reduced and the adhesive layer 50 can spread uniformly. The exemplary structure allows the adhesive layer 50 to easily enter gaps between fine projections and depressions in the second area 11B when the lid 30 and the substrate 10 are pressed against each other. Thus, the bonding strength exerted at the interface between the second area 11B and the adhesive layer 50 can be enhanced with compound effects of anchor effect, van der Waals force, and other effects. Moreover, making the surface roughness of the second area 11B greater than the surface roughness of the first area 11A can prevent the adhesive layer 50 from intruding into the recess 31. If the adhesive layer 50 intrudes into the recess 31, gas discharged from the adhesive layer 50 may adhere to the excitation electrodes 22 and 23, constituting an oscillation area of the piezoelectric oscillator 20, and this gas adhesion may change the oscillation frequency of the piezoelectric oscillator 20. Thus, preferably, the adhesive layer 50 is kept from intruding into the recess 31.

The flange portion 32 of the lid 30 includes a bonded surface 33, bonded to the second area 11B of the substrate 10 with the adhesive layer 50 interposed therebetween. The surface roughness of the bonded surface 33 is preferably greater than the surface roughness of the first area 11A of the substrate 10. This structure allows the adhesive layer 50 to easily spread over the bonded surface 33 of the flange portion 32, so that the bonding strength between the adhesive layer 50 and the lid 30 can be enhanced.

Each embodiment described above is provided for easy understanding of the present invention and not for limiting the present invention. It should be appreciated that the exemplary embodiment can be changed or modified without departing from the scope of the invention and includes equivalents thereof. Specifically, the scope of the present invention includes modifications formed by the persons skilled in the art appropriately changing the designs from those in each embodiment as long as they have characteristics of the present invention. For example, the components and the arrangement, the material, the conditions, the shape, and the size of the components of each embodiment are not limited to those described above and may be appropriately changed. Components of each embodiment can be combined if technically possible, and the combination of any of the components is also included in the scope of the present invention as long as it includes the characteristics of the present invention.

### REFERENCE SIGNS LIST

10 substrate
11 main surface
11A first area
11B second area
12 conductive adhesive
13 wire
14 indentation
15 conductive adhesive
16 wire
17 indentation
20 piezoelectric oscillator
21 piezoelectric plate
22 excitation electrode
23 excitation electrode
30 lid
31 recess
32 flange portion
40 piezoelectric oscillation component
50 adhesive layer

1. A piezoelectric vibration component, comprising:
a lid including a recess and a flange extending around an opening edge of the lid;
a substrate having a first surface area opposing the recess and a second surface area opposing the flange when the lid is affixed to the substrate;
a piezoelectric vibrator disposed on the first surface area of the substrate; and
an adhesive layer that bonds the second surface area of the substrate to the flange to seal the piezoelectric vibrator between the recess and the first surface area,
wherein the second surface area has surface roughness that is greater than a surface roughness of the first surface area.

2. The piezoelectric vibration component according to claim 1, wherein the flange extends outward from the opening edge of the lid.

3. The piezoelectric vibration component according to claim 1, wherein the flange has a bonded surface that is bonded to the second surface area of the substrate by the adhesive layer.

4. The piezoelectric vibration component according to claim 3, wherein the bonded surface has a surface roughness greater than the surface roughness of the first surface area.

5. The piezoelectric vibration component according to claim 1, wherein the adhesive layer comprises a glass adhesive.

6. The piezoelectric vibration component according to claim 5, wherein the glass adhesive contains a lead-free vanadium-based glass that melts at a temperature within a range of 300° C. to 410° C.

7. A piezoelectric vibration component, comprising:
a substrate having a first surface area with a first surface roughness and a second surface area with a second surface roughness that is greater than the first surface roughness of the first surface area;
a piezoelectric vibrator affixed to the first surface area of the substrate; and
a lid secured to at least a portion of the second surface area of the substrate to seal the piezoelectric vibrator between the lid and at least a portion of the first surface area of the substrate.

8. The piezoelectric vibration component according to claim 7, wherein the lid includes a recess, such that the piezoelectric vibrator is disposed within at least a portion of the recess when the lid is secured to the substrate.

9. The piezoelectric vibration component according to claim 8, wherein the lid includes a flange that extends outward from the recess around an opening edge of the lid.

10. The piezoelectric vibration component according to claim 9, wherein the flange has a bonded surface that is bonded to the second surface area of the substrate, and wherein the bonded surface has a surface roughness greater than the first surface roughness of the first surface area.

11. The piezoelectric vibration component according to claim 10, wherein the first surface area of the substrate opposes the recess and the second surface area of the substrate opposes the flange when the lid is secured to the substrate.

12. The piezoelectric vibration component according to claim 7, further comprising an adhesive layer that bonds the second surface area of the substrate to the lid.

13. A method for manufacturing a piezoelectric vibration component, the method comprising:
roughening only a portion of a surface area of a substrate, such that the roughened surface area has a greater surface than a remaining surface area of the substrate;
mounting a piezoelectric vibrator on at least a portion of the remaining surface area of the substrate;
providing an adhesive layer over the roughened surface area of the substrate; and
securing a lid to the roughened surface area of the substrate by the adhesive layer to seal the piezoelectric vibrator between the lid and the substrate.

14. The method for manufacturing a piezoelectric vibration component according to claim 13, wherein the roughening of the portion of the surface area of the substrate comprises sandblasting the portion of the surface area of the substrate.

15. The method for manufacturing a piezoelectric vibration component according to claim 13, further comprising preparing the lid to include a recess, such that the piezoelectric vibrator is disposed within at least a portion of the recess when the lid is secured to the substrate.

16. The method for manufacturing a piezoelectric vibration component according to claim 15, further comprising preparing the lid to include a flange that extends outward from the recess around an opening edge of the lid.

17. The method for manufacturing a piezoelectric vibration component according to claim 16, further comprising roughening a surface area of the flange to have a surface roughness greater than a surface roughness of the remaining surface area of the substrate.

18. The method for manufacturing a piezoelectric vibration component according to claim 17, further comprising securing the roughened surface area of the flange by the adhesive layer to the roughened surface area of the substrate.

19. The method for manufacturing a piezoelectric vibration component according to claim 18, wherein the remaining surface area of the substrate opposes the recess and the roughened surface area of the substrate opposes the flange when the lid is secured to the substrate.

20. The method for manufacturing a piezoelectric vibration component according to claim 13, wherein the adhesive layer comprises a glass adhesive that contains a lead-free vanadium-based glass that melts at a temperature within a range of 300° C. to 410° C.
